(19) United States
(12) Patent Application Publication
(10) Pub. No.: US 2011/0044003 A1
(43) Pub. Date: Feb. 24, 2011

(54) Heatsink structure

(76) Inventor: Huang-Han CHEN, Taipei Hsien (TW)

Correspondence Address: Muncy, Geissler, Olds & Lowe, PLLC, 4000 Legato Road, Suite 310, FAIRFAX, VA, 22033, US

(21) Appl. No.: 11/826,698

(22) Filed: Jul. 17, 2007

(51) Int. Cl. H05K 7/20

(52) U.S. Cl. 361/709

(57) ABSTRACT

An improved heatsink structure is disclosed. The present invention provides a type of heatsinks formed by stacking a plurality of particulates, in order to achieve a larger heat-dissipation surface area and higher heat-dissipation efficiency.

### BACKGROUND OF THE INVENTION

(a) Field of the Invention

The present invention relates to an improved heatsink structure, particularly a heatsink structure applicable to a computer chip, such that heat generated during chip processing is dissipated in order to maintain normal operations of the computer chip.

(b) Description of the Prior Art

A heatsink is mounted on a computer circuit board in close contact with a computer chip, such that the heatsink conducts the heat generated during chip processing to a surface of the heatsink. By using a fan, air is drawn for heat exchange on the surface of the heatsink, such that sufficient fresh air is available for heat dissipation in the computer chip to maintain its normal operations.

Referring to FIGS. 1 and 2, a plurality of fins 11 are mounted on a surface of a conventional heatsink 10 to increase heat-dissipating surface area and thermal conversion efficiency.

Given the higher processing speed of computer chips nowadays, temperature generated by computer chips becomes higher. Consequently, by increasing the volume of heatsinks and the number of fins, the heat-dissipating surface area is increased to maintain normal operations of the computer chips. However, this method greatly squeezes the space inside computers, particularly for notebook computers. Given notebook computers are characterized by thinness and compactness, reduced processing speed due to heat dissipation has long been a drawback to be overcome for notebook computers.

The conventional process of fabricating heatsinks includes the steps of fabricating a set of aluminum extrusion molds, cutting the molds to the actual heatsink size after extruding the aluminum materials, polishing and trimming the edges so formed, and further processing of the heatsink using an anode to enhance the heatsink appearance. However, this conventional process is overly complicated, not satisfactorily productive and costly.

### SUMMARY OF THE INVENTION

To overcome the above drawbacks, a primary object of the invention is to provide a suitable heatsink structure, wherein the heatsink has a more spacious surface area conducive to higher thermal conversion efficiency. In this way, higher thermal dissipation efficiency is achieved using heatsinks with the same volume, or the same thermal dissipation efficiency is achieved by using even smaller heatsinks. This fabrication process thus becomes simpler, highly productive and less costly.

To enable a further understanding of the objectives and the technological methods of the invention herein, the brief description of the drawings below is followed by the detailed description of the preferred embodiments.

### BRIEF DESCRIPTION OF THE DRAWINGS

FIG. 1 is a schematic view of a conventional heatsink;

FIG. 2 is a schematic view of a conventional heatsink;

FIG. 3 is a schematic view of the present invention;

FIG. 4 is a schematic view of the present invention;

FIG. 5 is a two-dimensional schematic view and a detailed, magnified view of the present invention; and

FIG. 6 is a schematic view illustrating an embodiment of the present invention.

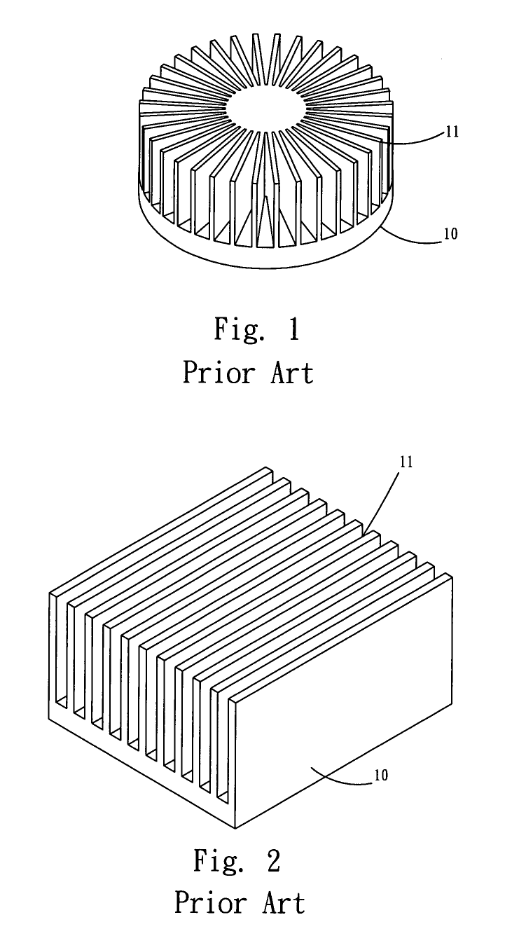

### DETAILED DESCRIPTION OF THE PREFERRED EMBODIMENTS

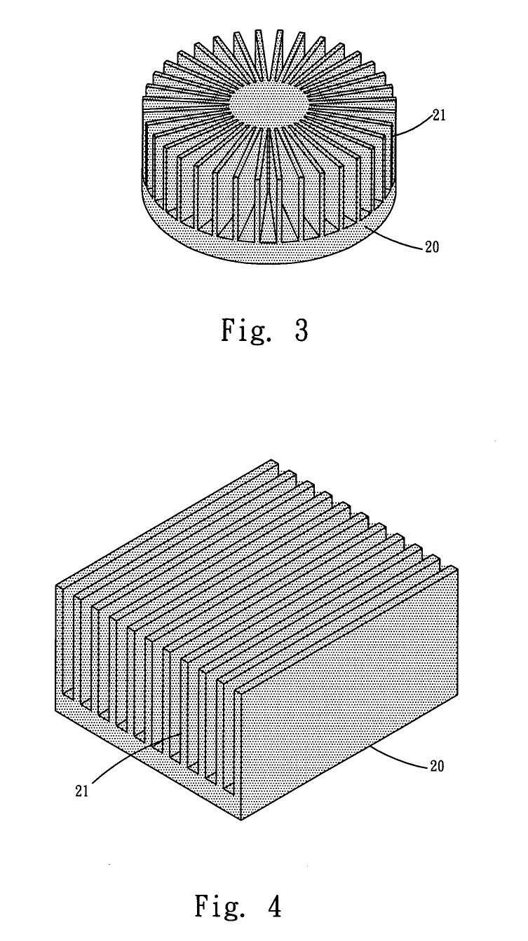

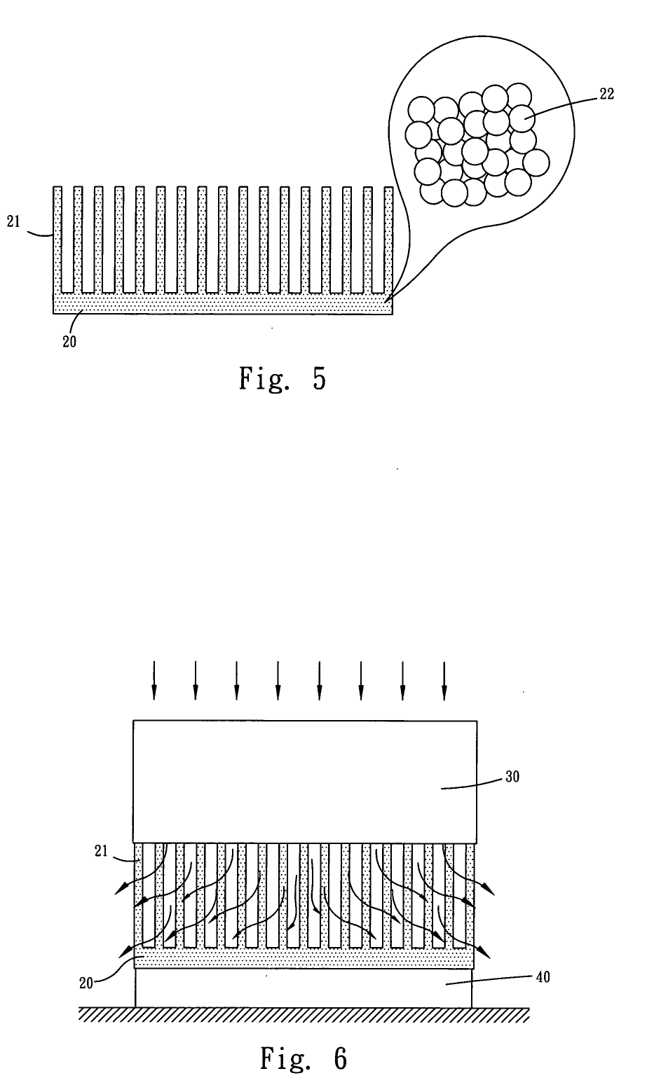

Referring to FIGS. 3, 4 and 5, an improved heatsink structure of the present invention includes a substrate 20 attached onto a computer chip. A plurality of fins 21 extends upward from the substrate 20, wherein the substrate 20 and the fins 21 are formed by stacking a plurality of particulates 22 (See FIG. 5). Moreover, adjacent particulates 22 are so tightly bound and integrated that the particulates do not fall off under external forces.

Referring to FIG. 5, the adjacent particulates 22 are tightly bound as an integrated unit, but it is only a point-to-point connection. In addition to the binding sites of the particulates, most of the remaining spaces will come into contact with air. By doing so, the total surface area is increased by several times to thousand times. Moreover, the surface area is entirely determined by the particulate size. In other words, if a heatsink is formed by stacking smaller particulates 22, the surface area of the heatsink becomes larger, but the gaps between the particulates 22 become closely tight. On the other hand, if a heatsink is formed by stacking larger particulates 22, the surface area of the heatsink becomes smaller, but the gaps between the particulates 22 are loose and not dense.

Referring to FIG. 6, when mounting the present invention on a computer chip 40 together with a fan 30, the high temperature generated during the processing of the computer chip 40 is conducted from the substrate 20 to fins 21. The fan 30 blows colder air from the environment to the fins 21 and the substrate 20, such that the colder air flows around the gaps between the particulates 22 for maximizing thermal conversion efficiency.

By modifying the appearance and the size of heatsinks, the surface area of heatsinks is maximized, thereby maximizing the heat-dissipation efficiency of the heatsinks. This method reduces the size of heatsinks and achieves the expected heat-dissipation effects, particularly for chips inside notebook computers.

Only one set of multiple-cavity molds needs to be formed during fabricating the present invention. After particulates are poured into the molds, pressurized and heated, heatsinks are constituted. Neither cutting nor trimming is required for the fabrication of the present invention. Moreover, the raw materials are very simple and are free from the problem of waste generation, thereby greatly reducing production costs.

It is of course to be understood that the embodiment described herein is merely illustrative of the principles of the invention and that a wide variety of modifications thereto may be effected by persons skilled in the art without departing from the spirit and scope of the invention as set forth in the following claims.

What is claimed is:

1. A heatsink structure, comprising:
a substrate attached onto a chip; a plurality of fins extending upward from the substrate, wherein the substrate and the plurality of fins are formed by stacking a plurality of particulates.
